(19) United States
(12) Patent Application Publication
(10) Pub. No.: US 2015/0295006 A1
(43) Pub. Date: Oct. 15, 2015

(54) LIGHT SENSING DEVICE AND MANUFACTURING METHOD THEREOF

(71) Applicant: AU OPTRONICS CORP., HSIN-CHU (TW)

(72) Inventors: Ching-Wen Chen, Hsin-Chu (TW); An-Thung Cho, Hsin-Chu (TW); Jiun-Jye Chang, Hsin-Chu (TW); Chun Chang, Hsin-Chu (TW)

(21) Appl. No.: 14/554,072

(22) Filed: Nov. 26, 2014

(30) Foreign Application Priority Data
Apr. 15, 2014 (TW) 103113752

(51) Int. Cl. H01L 27/146; H01L 29/66; H01L 31/0224; H01L 31/18; H01L 29/786; H01L 31/105

(52) U.S. Cl. CPC H01L 27/14643; H01L 27/14616; H01L 29/7869; H01L 27/14623; H01L 31/105; H01L 27/14685; H01L 31/022466; H01L 31/1884; H01L 29/66969

(57) ABSTRACT

A light sensing device includes a substrate, a control unit and a light sensing unit. The control unit and the light sensing unit are disposed on the substrate. The control unit includes a gate electrode, a gate insulation layer, an oxide semiconductor pattern, a source electrode and a drain electrode. The gate insulation layer is disposed on the gate electrode, and the oxide semiconductor pattern is disposed on the gate insulation layer. The light sensing unit includes a bottom electrode, a light sensing diode and a top electrode. The light sensing diode is disposed on the bottom electrode, and the top electrode is disposed on the light sensing diode. The gate insulation layer partially covers the top electrode, and the gate insulation layer has a first opening partially exposing the bottom electrode. The drain electrode is electrically connected to the bottom electrode via the first opening.

### BACKGROUND OF THE INVENTION

1. Field of the Invention

The present invention relates to a light sensing device and a manufacturing method thereof, and more particularly, to a light sensing device having an oxide semiconductor control unit, and a manufacturing method thereof.

2. Description of the Prior Art

In general light sensing devices, a control unit is usually disposed in a light sensing unit to control the switching of the sensing unit and to read the signals, and the thin film transistor (TFT) is usually used as a control unit in the industry. However, the semiconductor character of the control unit is easy to be affected by the manufacturing conditions during manufacturing the sensing unit, leading to the instability of the electrical property of the control unit, and affecting the entire operation of the light sensing device and the quality of products in further.

### SUMMARY OF THE INVENTION

It is one of the objectives of the present invention to provide a light sensing device and a manufacturing method thereof, through forming a light sensing unit firstly before forming the oxide semiconductor pattern in the control unit, to keep the manufacturing process of the light sensing unit from affecting the electric property of the oxide semiconductor pattern, so as to achieve the purpose of improving the component quality of the control unit and the yield of the products.

To achieve the purpose described above, the present invention provides a light sensing device including a substrate, a control unit, and a light sensing unit. The control unit and the light sensing unit are disposed on the substrate. The control unit includes a gate electrode, a gate insulation layer, an oxide semiconductor pattern, a source electrode and a drain electrode. The gate insulation layer is disposed on the gate electrode, and the oxide semiconductor pattern is disposed on the gate insulation layer. The source electrode and the drain electrode are disposed corresponding to the oxide semiconductor pattern. The light sensing unit includes a bottom electrode, a light sensing diode and a top electrode. The light sensing diode is disposed on the bottom electrode, and the top electrode is disposed on the light sensing diode. The gate insulation layer partially covers the top electrode, the gate insulation layer has a first opening partially exposing the bottom electrode, and the drain electrode is electrically connected to the bottom electrode via the first opening.

To achieve the purpose described above, the present invention provides a manufacturing method of a light sensing device including following steps. Firstly, a substrate is provided. Then, a gate electrode and a light sensing unit are formed on the substrate. The light sensing unit includes a bottom electrode, alight sensing diode, and a top electrode. The light sensing diode is disposed on the bottom electrode, and the top electrode is disposed on the light sensing diode. Next, agate insulation layer is formed, covering the substrate, the gate electrode and the light sensing unit. After that, an oxide semiconductor pattern is formed on the gate insulation layer, a first opening is formed in the gate insulation layer, and the bottom electrode is partially exposed from the first opening. A source electrode and a drain electrode are formed on the gate insulation layer. Those stacked gate electrode, gate insulation layer, oxide semiconductor pattern, source electrode and drain electrode compose a control unit, and the drain electrode is electrically connected to the bottom electrode via the first opening.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 are schematic diagrams illustrating a manufacturing method of a light sensing device according to a first embodiment of the present invention.

FIG. 8 and FIG. 9 are schematic diagrams illustrating a manufacturing method of a light sensing device according to a second embodiment of the present invention.

FIG. 10 is a schematic diagram illustrating a light sensing device according to a third embodiment of the present invention.

FIG. 11 is a schematic diagram illustrating a light sensing device according to a fourth embodiment of the present invention.

FIG. 12 is a schematic diagram illustrating a light sensing device according to a fifth embodiment of the present invention.

FIG. 13 is a schematic diagram illustrating a light sensing device according to a sixth embodiment of the present invention.

### DETAILED DESCRIPTION

In the following description, numerous specific details, as well as accompanying drawings, are given to provide a thorough understanding of the invention. It will, however, be apparent to one skilled in the art that the invention may be practiced without these specific details.

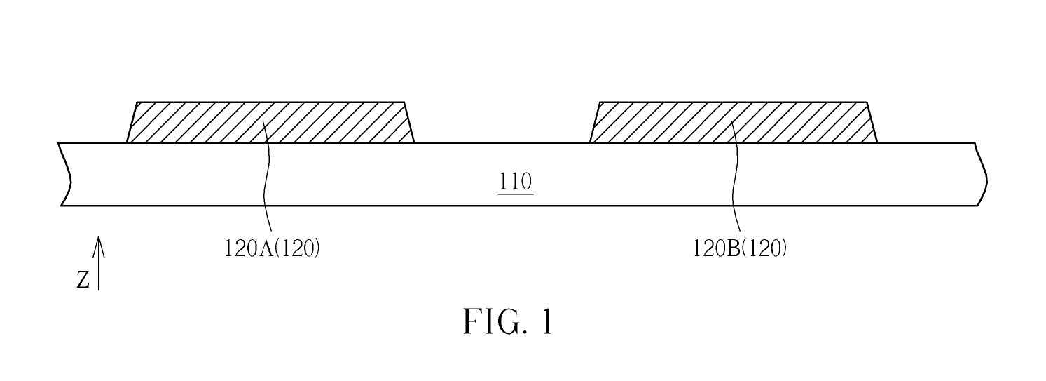

Please refer to FIGS. 1-7. FIGS. 1-7 are schematic diagrams illustrating a manufacturing method of a light sensing device according to a first embodiment of the present invention. Please note that, the drawings are given to provide ease of explanation and for illustrating a preferable embodiment of the present invention, and a modification of the detail scale thereof is allowable, according to practical requirements. The manufacturing method of the light sensing device according to the present embodiment includes the following steps. Firstly, as shown in FIG. 1, a substrate 110 is provided. The substrate 110 may include a rigid substrate, such as a glass substrate and a ceramic substrate; or a flexible substrate, such as a plastic substrate or a substrate made of other suitable materials. Then, a first conductive layer 120 is formed on the substrate 110, the first conductive layer 120 may include at least one of aluminum (Al), copper (Cu), silver (Ag), chromium (Cr), titanium (Ti), molybdenum (Mo), a composition of the aforementioned materials, and an alloy of at least one of aforementioned materials, but not limited to, and the first conductive layer 120 can also include other conductive material. Next, a patterning process is performed on the first conductive layer 120, to form a gate electrode 120A and a bottom electrode 120B, with the gate electrode 120A and the bottom electrode 120B being separated from each other. In other words, the gate electrode 120A and the bottom electrode 120B are formed by patterning the same layer of the conductive layer (namely, the first conductive layer 120), but the present invention is not limited thereto. In another embodiment of the present invention, the gate electrode 120A and the bottom electrode 120B can also be formed respectively by using different conductive layers, in accordance with the practical requirements.

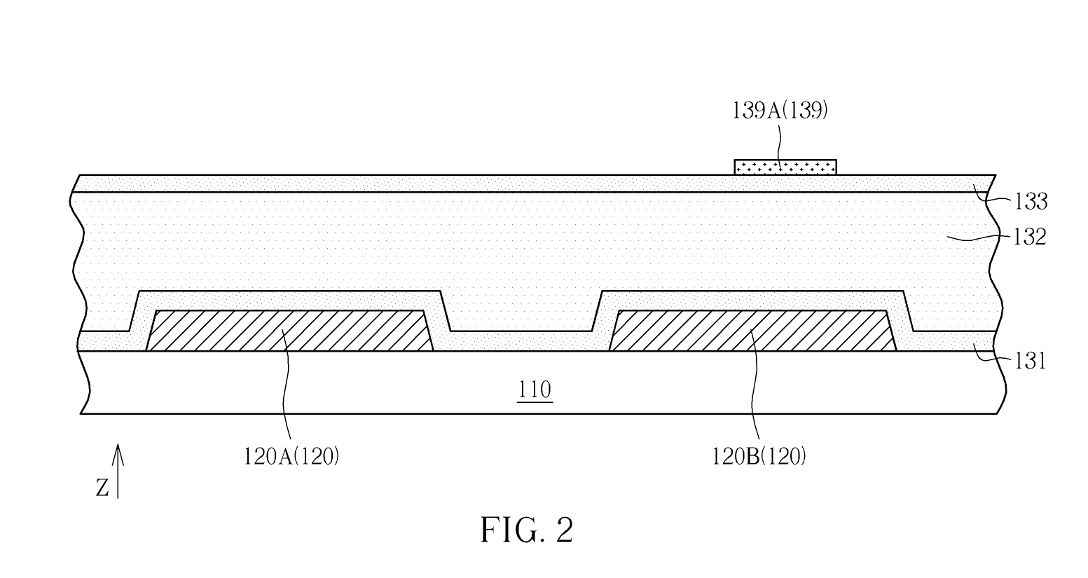

Then, as shown in FIG. 2, an N type semiconductor layer 131, an intrinsic semiconductor layer 132, and a P type semiconductor layer 133 are sequentially formed on the substrate 110, the gate electrode 120A and the bottom electrode 120B. The material of the intrinsic semiconductor layer 132 may include intrinsic amorphous silicon, the material of the N type semiconductor layer 131 may include N type doped amorphous silicon, and the material of the P type semiconductor layer 133 may include P type doped amorphous silicon, but not limited thereto. Therefore, the N type semiconductor layer 131, the intrinsic semiconductor layer 132, and the P type semiconductor layer 133 can be formed sequentially through the same manufacturing process, such as chemical vapor deposition (CVD) process, by inhaling different required reaction gas, but not limited thereto. In another embodiment of the present invention, the N type semiconductor layer 131, the intrinsic semiconductor layer 132, and the P type semiconductor layer 133 can also be formed through other different manufacturing processes, by using other different materials, in accordance with practical requirements. Next, a first transparent conductive layer 139 is then formed on the P type semiconductor layer 133, and the first transparent conductive layer 139 may include indium tin oxide (ITO), indium zinc oxide (IZO), aluminum zinc oxide (AZO) or other suitable transparent conductive materials. Then the first transparent conductive layer 139 is patterned, to form a top electrode 139A on the P type semiconductor layer 133.

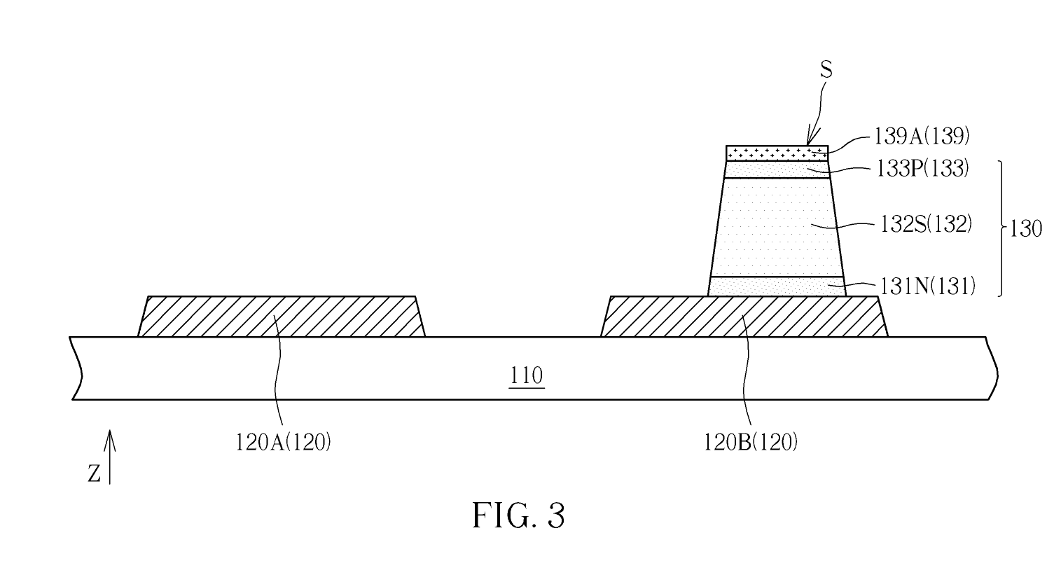

After that, as shown in FIG. 3, the N type semiconductor layer 131, the intrinsic semiconductor layer 132 and the P type semiconductor layer 133 are patterned, to form an N type semiconductor pattern 131N, an intrinsic semiconductor pattern 132S, and a P type semiconductor pattern 133P stacked with each other in a vertical projection direction Z, and to form a light sensing diode 130 consisted of the N type semiconductor pattern 131N, the intrinsic semiconductor pattern 132S, and the P type semiconductor pattern 133P in further. The vertical projection direction Z is substantially vertical to the substrate 110, but not limited thereto. In the present embodiment, the bottom electrode 120B, the light sensing diode 130 and the top electrode 139A compose a light sensing unit S. That is said that the light sensing unit S includes the bottom electrode 120B, the light sensing diode 130 and the top electrode 139A. The light sensing diode 130 is disposed on the bottom electrode 120B, and the top electrode 139A is disposed on the light sensing diode 130. The top electrode 139A of the present embodiment is preferably formed before the N type semiconductor pattern 131N, the intrinsic semiconductor pattern 132S, and the P type semiconductor pattern 133P are formed, such that it is sufficient to keep the quality of the intrinsic semiconductor layer 132 from being affected during patterning the first transparent conductive layer 139, but not limited thereto. In another embodiment of the present invention, the sequence of forming the top electrode 139A and the light sensing diode 130 can also be adjusted, in accordance with the practical requirements.

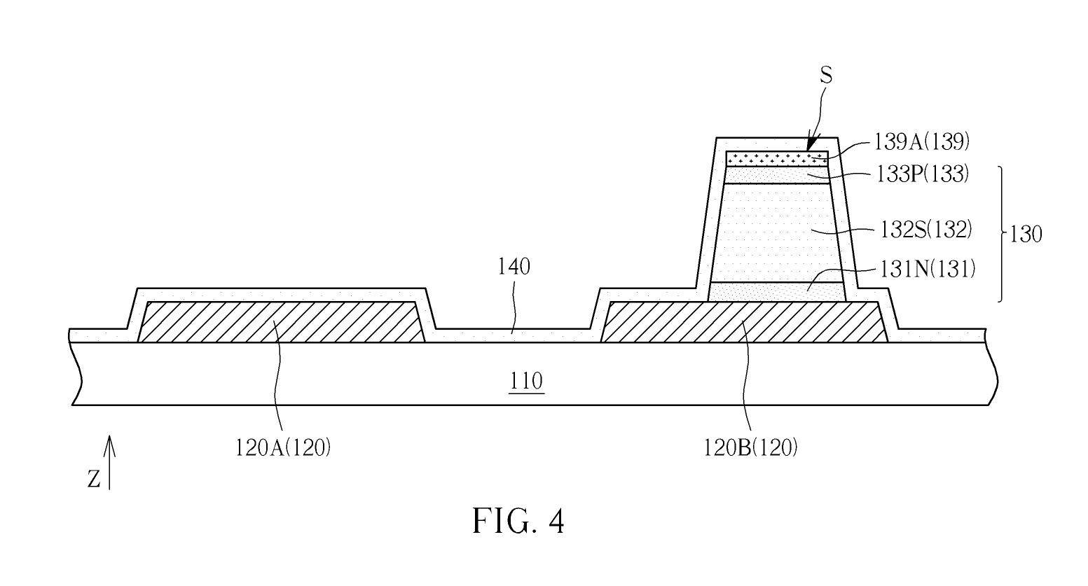

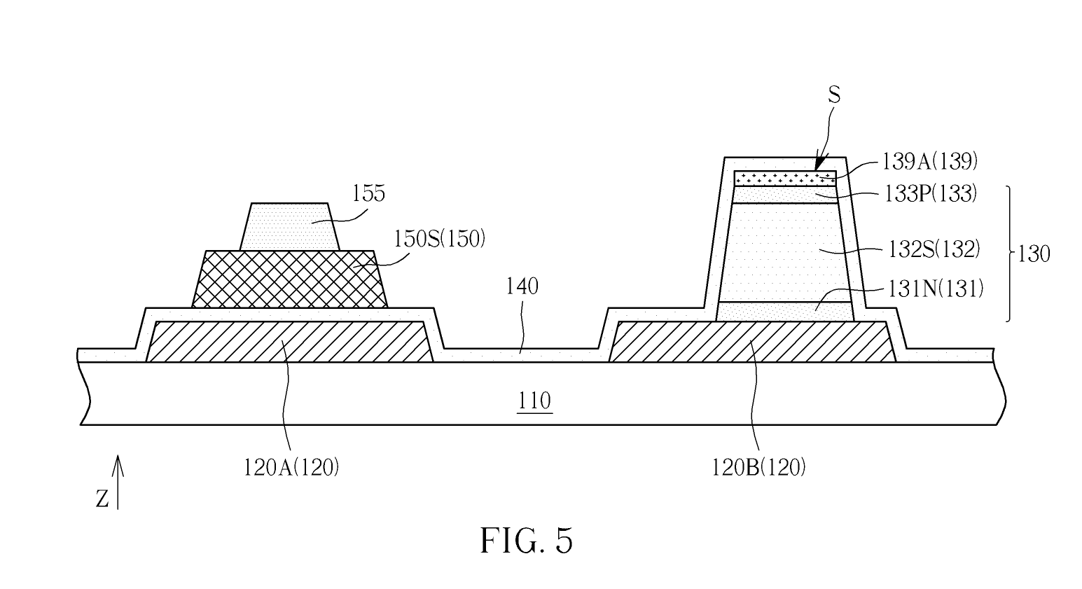

Next, as shown in FIG. 4, a gate insulation layer 140 is formed, covering the substrate 110, the gate electrode 120A and the light sensing unit S. The gate insulation layer 140 may include inorganic material, such as silicon nitride, silicon oxide, and silicon oxynitride; organic material, such as acrylic resin; or other suitable dielectric materials. After that, as shown in FIG. 5, an oxide semiconductor layer 150 is formed on the gate insulation layer 140, and the oxide semiconductor layer 150 is patterned to formed an oxide semiconductor pattern 150S. The material of the oxide semiconductor layer 150 may include a group II-VI compound, such as zinc oxide (ZnO); a group II-VI compound doped alkaline earth metal, such as zinc magnesium oxide (ZnMgO); a II-VI compound doped IIIA element, such as indium gallium zinc oxide (IGZO); a II-VI compound doped group VA elements, such as tin antimony oxide (SnSbO₂); a II-VI compound doped group VIA element, such as oxidized zinc selenide (ZnSeO); a II-VI compound doped transition metal, such as zirconium doped zinc oxide (ZnZrO); or other oxides having semiconductor property and consisted of the aforementioned elements. Then, an etching stop layer 155 is formed on the oxide semiconductor pattern 150S, and the material of the etching stop layer 155 may include silicon nitride, silicon oxide, silicon oxynitride or other suitable insulation materials. It is worth mentioning that, in another embodiment of the present embodiment, the etching stop layer 155 can also be formed on the oxide semiconductor layer 150 before the oxide semiconductor layer 150 is patterned, and the oxide semiconductor layer 150 is then patterned after the etching stop layer 155 is formed, to form the oxide semiconductor pattern 150S.

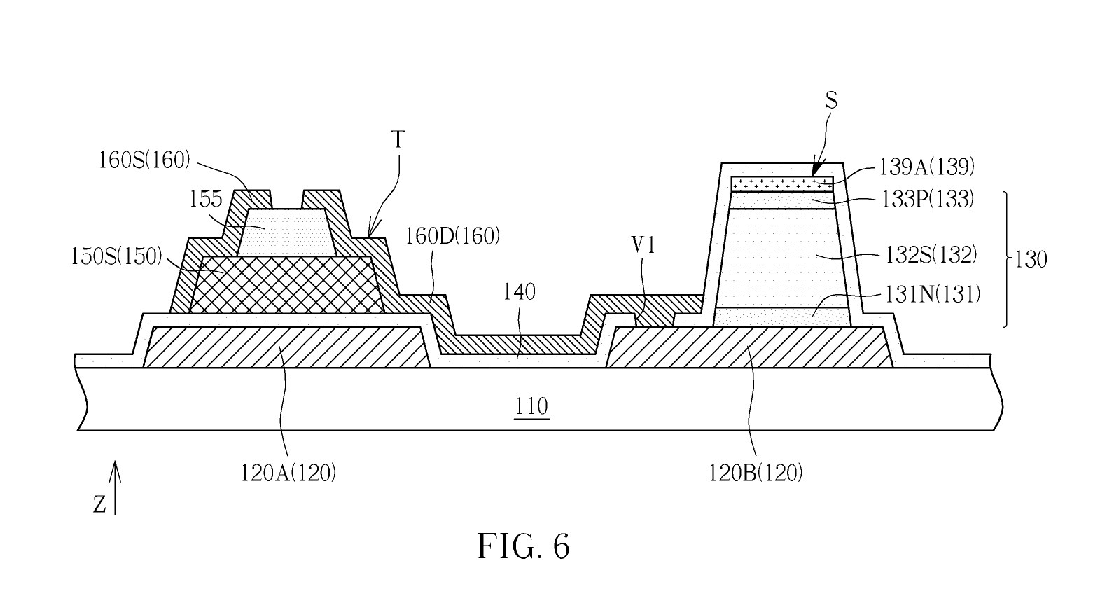

As shown in FIG. 6, a first opening V1 is formed in the gate insulation layer 140, and a second conductive layer 160 is formed on the gate insulation layer 140. The second conductive layer 160 may include metal material, such as at least one of aluminum, copper, silver, chromium, titanium and molybdenum, a composition of the aforementioned materials, or an alloy of at least one of the aforementioned materials, but not limited thereto, and the second conductive layer 160 can also include other conductive materials. After that, a patterning process is performed on the second conductive layer 160 to formed a source electrode 160S and a drain electrode 160D. The stacked gate electrode 120A, gate insulation 140, oxide semiconductor pattern 150S, etching stop layer 155, source electrode 160S, and drain electrode 160D compose a control unit T positioned on the substrate 110. The first opening V1 of the gate insulation layer 140 partially exposes the bottom electrode 120B, and the drain electrode 160D is electrically connected to the bottom electrode 120B via the first opening V1. The source electrode 160S and the drain electrode 160D are formed after the oxide semiconductor pattern 150S is formed, and the oxide semiconductor pattern 150S is positioned between the gate insulation layer 140 and the source electrode 160S, and between the gate insulation layer 140 and the drain electrode 160D. The source electrode 160S and the drain electrode 160D are disposed corresponding to the oxide semiconductor pattern 150S. The etching stop layer 155 is formed on the oxide semiconductor pattern 150S before the source electrode 160S and the drain electrode 160D are formed, and the etching stop layer 155 is disposed between the oxide semiconductor pattern 150S and the source electrode 160S, and between the oxide semiconductor pattern 150S and the drain electrode 160D, for protecting the oxide semiconductor pattern 150S and avoiding the damage to the oxide semiconductor pattern 150S during patterning the second conductive layer 160.

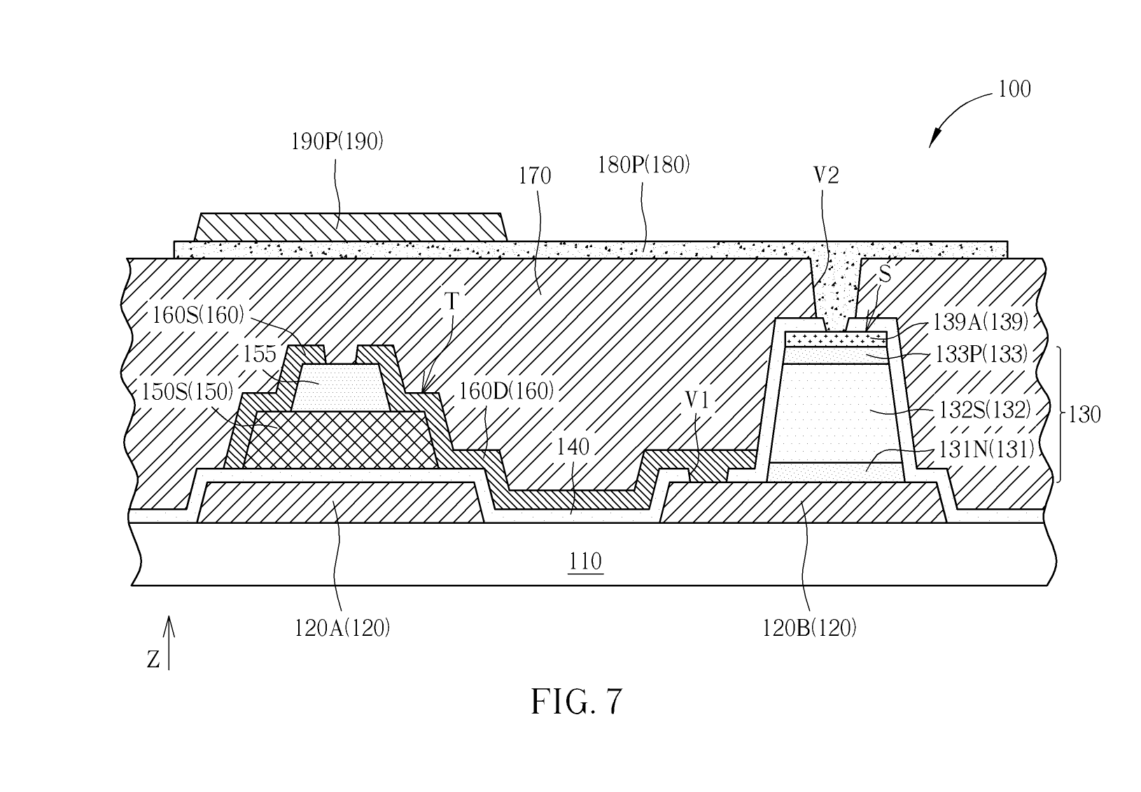

Next, as shown in FIG. 7, a protection layer 170 is formed, covering the control unit T and the light sensing unit S, and a second opening V2 is formed in the protection layer 170 and the gate insulation layer 140. The second opening V2 penetrates the protection layer 170 and the gate insulation layer 140 to at least partially expose the top electrode 139A. The protection layer 170 may include inorganic material, such as silicon nitride, silicon oxide, and silicon oxynitride; organic material, such as acrylic resin; or other suitable insulation materials. Then, a second transparent conductive layer 180 is formed on the protection layer 170, covering the second opening V2, and the second transparent conductive layer 180 is patterned to form a transparent conductive pattern 180P. The transparent conductive pattern 180P is electrically connected to the top electrode 139A via the second opening V2. Through the aforementioned steps, a light sensing device 100 as shown in FIG. 7 can be formed. In addition, the method of present embodiment may further include forming a light shielding pattern 190P on the transparent conductive pattern 180P, and the light shielding pattern 190P at least partially overlaps the control unit T, in order to avoid the light illuminating on the oxide semiconductor pattern 150S in the control unit T, which may result in the anomaly of the control unit T during the operation. The light shielding pattern 190P of the present embodiment can be formed by forming a third conductive layer 190 on the transparent conductive pattern 180P and patterning the third conductive layer 190, such that the light shielding pattern 190P is electrically connected to the transparent conductive pattern 180P, but the present invention is not limited thereto. In another embodiment of the present invention, non-conductive material can also be used to form the light shielding pattern 190P, according to the practical requirements.

As shown in FIG. 7, the light sensing device 100 of the present embodiment includes the substrate 110, the control unit T, the light sensing unit S, the protection layer 170, the transparent conductive pattern 180P and the light shielding patter 190P. The control unit T and the light sensing unit S are disposed on the substrate 110. The control unit T includes the gate electrode 120A, the gate insulation layer 140, the oxide semiconductor pattern 150S, the etching stop layer 155, the source electrode 160S and the drain electrode 160D. The gate insulation layer 140 is disposed on the gate electrode 120A, and the oxide semiconductor pattern 150S is disposed on the gate insulation layer 140. The light sensing unit S includes the bottom electrode 120B, the light sensing diode 130 and the top electrode 139A. The light sensing diode 130 is disposed on the bottom electrode 120B, and the top electrode 139A is disposed on the light sensing diode 130. The gate insulation layer 140 partially overlaps the top electrode 139A and the bottom electrode 120B, the gate insulation layer 140 has a first opening V1 partially exposing the bottom electrode 120B, and the drain electrode 160D is electrically connected to the bottom electrode 120B via the first opening V1. The protection layer 170 covers the control unit T and the light sensing unit S, and the light sensing device 100 has a second opening V2 penetrating the protection layer 170 and the gate insulation layer 140, to at least partially expose the top electrode 139A. In the present embodiment, the gate insulation layer 140 preferably covers the side edge of the light sensing diode 130, but not limited thereto. The transparent conductive pattern 180P is disposed on the protection layer 170, and the transparent conductive pattern 180 is electrically connected to the top electrode 139A via the second opening V2. The light shielding pattern 190P is disposed on the transparent conductive pattern 180P and is electrically connected to the transparent conductive pattern 180P. The light shielding pattern 190P at least partially overlaps the control unit T, with such arrangement to avoid the light illuminating on the control unit T. The light sensing diode 130 of the present embodiment can be consisted of the N type semiconductor pattern 131N, the intrinsic semiconductor pattern 132S and the P type semiconductor pattern 133P, but not limited thereto. The intrinsic semiconductor pattern 132S is disposed on the N type semiconductor pattern 131N, and the P type semiconductor pattern 133P is disposed on the intrinsic semiconductor pattern 132S. While the external light irradiates the light sensing diode 130, the light sensing diode 130 will generate photocurrent, thereby achieving the light sensing effect through detecting such electrical variations.

More precisely speaking, in the light sensing device 100 of the present embodiment, a common voltage is applied to the top electrode 139A via the transparent conductive pattern 180P. Also, a reference voltage can be applied to the bottom electrode 120B while the control unit T is turned on, and the control unit T is then closed after the reference voltage is applied, with such performance to form an electric capacity status in the light sensing diode 130. Meanwhile, the light sensing diode 130 will generate photocurrent to change the electric capacity status if the light sensing diode 130 is irradiated by light. Therefore, the control unit T can obtain the electrical variations generated by the light sensing diode 130 due to the light irradiation when the control unit T is turned on again, so that the corresponding variations of the light can be calculated. Additionally, the light sensing device 100 of the present embodiment can further include a light transference layer (not shown in the drawings), and the light transference layer is configured to convert the non-visible light, such as X-ray, into the light which can lead to the photocurrent in the light sensing diode 130, such that the light sensing device 100 of the present embodiment can be used as a X-ray sensor, but not limited thereto. It is worth mentioning that, since the oxide semiconductor pattern 150S in the control unit T is formed after the sensing unit S is formed, it is sufficient to avoid the damage to the oxide semiconductor pattern 150S during the manufacturing process of the sensing unit S, thereby achieving the purpose of improving the component quality of the control unit T and increasing the yield of the products. Also, the light shielding pattern 190P is preferably electrically connected to the transparent conductive pattern 180P and has a fixed potential, so as to keep the instability of the potential of the light shielding pattern 190P from affecting the operation of the light sensing device 100.

The following description will detail the other embodiments of the touch device according to the present invention. To simplify the description, the following description will detail the dissimilarities among those embodiments and the variant embodiments and the identical features will not be redundantly described. In order to compare the differences between the embodiments easily, the identical components in each of the following embodiments are marked with identical symbols.

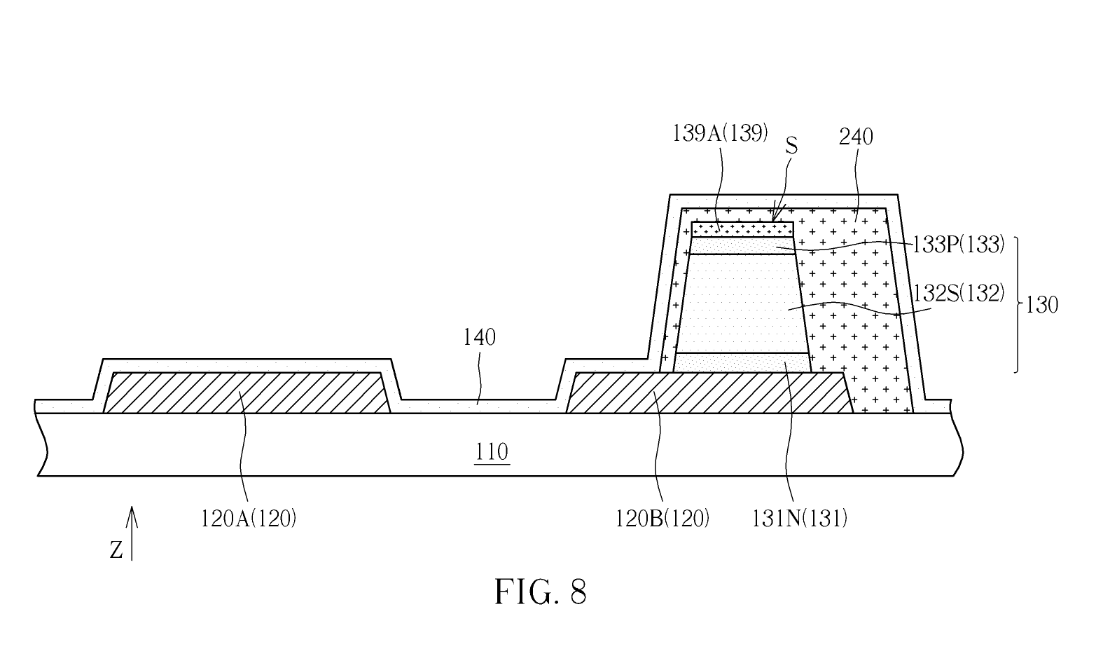

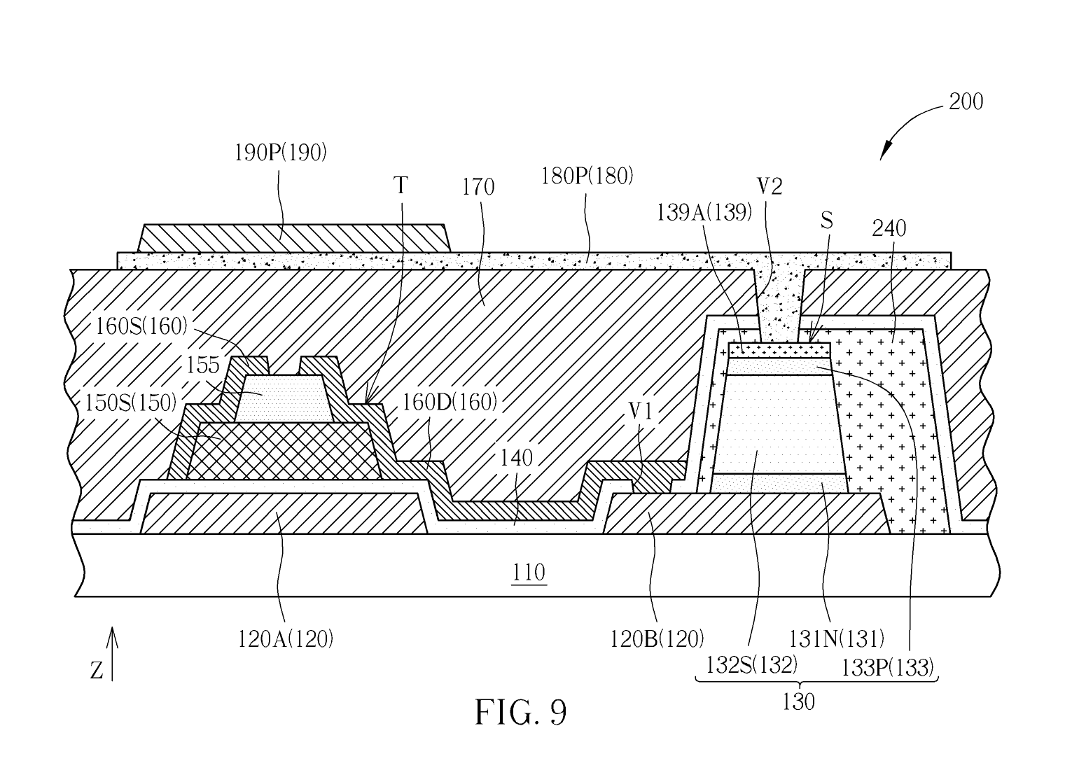

Referring to FIG. 8 and FIG. 9, FIG. 8 and FIG. 9 are schematic diagrams illustrating a manufacturing method of a light sensing device according to a second embodiment of the present invention. As shown in FIG. 8, in comparison with the aforementioned first embodiment, the manufacturing method of the light sensing device according to the present embodiment further includes forming an insulation pattern 240 on the light sensing unit S before the gate insulation layer 140 is formed, with such insulation pattern 240 covering the top electrode 139A, the light sensing diode 130 and a portion of the bottom electrode 120B. Next, as shown in FIG. 9, the second opening V2 is formed in the insulation pattern 240, the gate insulation layer 140 and the protection layer 170 after the gate insulation layer 140 and the protection layer 170 is formed, to partially expose the top electrode 139A, such that the transparent conductive pattern 180P is electrically connected to the top electrode 139A via the second opening V2 so as to formed the light sensing device 200 as shown in FIG. 9. In other words, in comparison with the light sensing device of the aforementioned first embodiment, the light sensing device 200 of the present embodiment further includes the insulation pattern 240, the insulation patter 240 partially covers the light sensing diode 130, and the insulation pattern 240 is disposed between the light sensing diode 130 and the gate insulation layer 140. In addition, the second opening V2 of the present embodiment penetrates the protection layer 170, the gate insulation layer 140 and the insulation pattern 240 to partially expose the top electrode 139A. It is worth mentioning that, the material and the thickness of the gate insulation layer 140 are generally limited to the cooperation with the oxide semiconductor pattern 150S, and the insulation pattern 240 in the present embodiment can be used to make up for the inadequate protection of the gate insulation layer 140 having limited material and thickness. For example, if the gate insulation layer 140 has to be made of silicon oxide due to the cooperation with the oxide semiconductor pattern 150S, the insulation pattern 240 can be made of a material of silicon nitride with relatively better water-blocking ability, so as to strengthen the protection to the light sensing diode 130. However, the material of the insulation pattern 240 is not limited to the aforementioned material of silicon nitride. In another embodiment of the present invention, the insulation pattern 240 can also include other suitable insulation materials, such as silicon oxynitride; or other suitable organic insulation materials, inorganic insulation materials or hybrid organic-inorganic insulation materials. Furthermore, in the present embodiment, the insulation pattern 240 preferably covers the side edge of the light sensing diode 130, to achieve the protection effect, but not limited thereto.

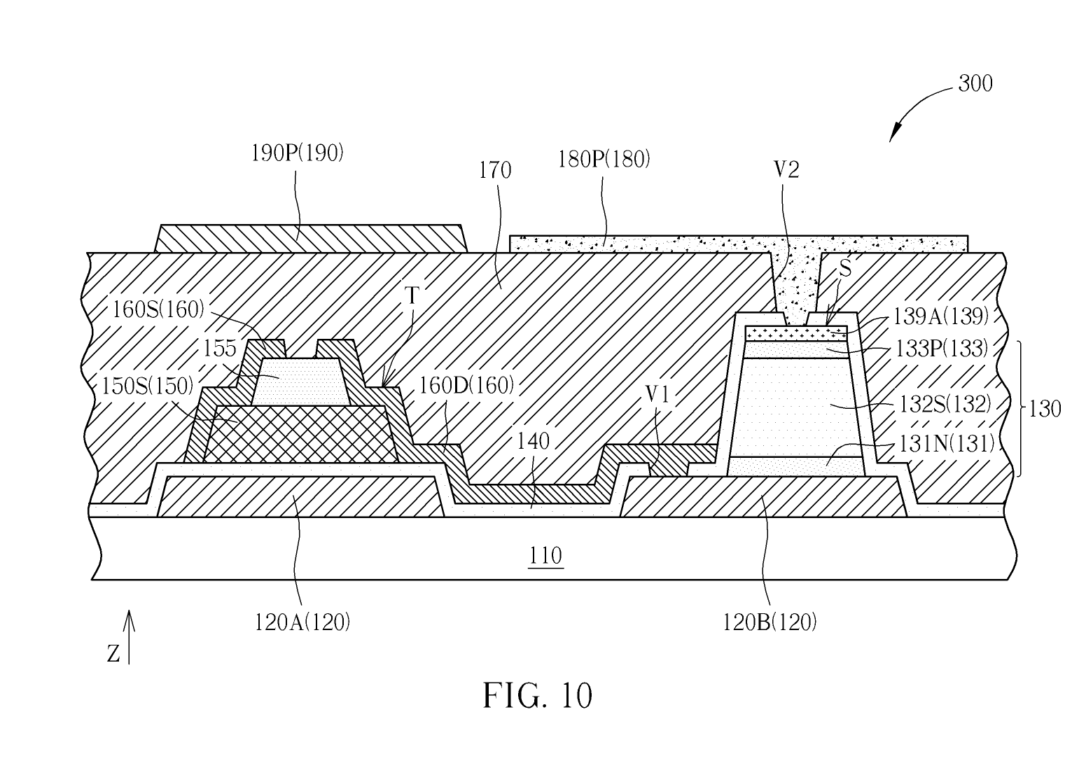

Referring to FIG. 10, FIG. 10 is a schematic diagram illustrating a light sensing device according to a third embodiment of the present invention. As shown in FIG. 10, the difference between the light sensing device 300 of the present embodiment and the aforementioned first embodiment is in that the light shielding pattern 190P of the present embodiment is disposed on the protection layer 170, the light shielding pattern 190P at least partially overlaps the control unit T but fail to overlap the transparent conductive pattern 180P, and the light shielding pattern 190P is electrically isolated from the transparent conductive pattern 180P.

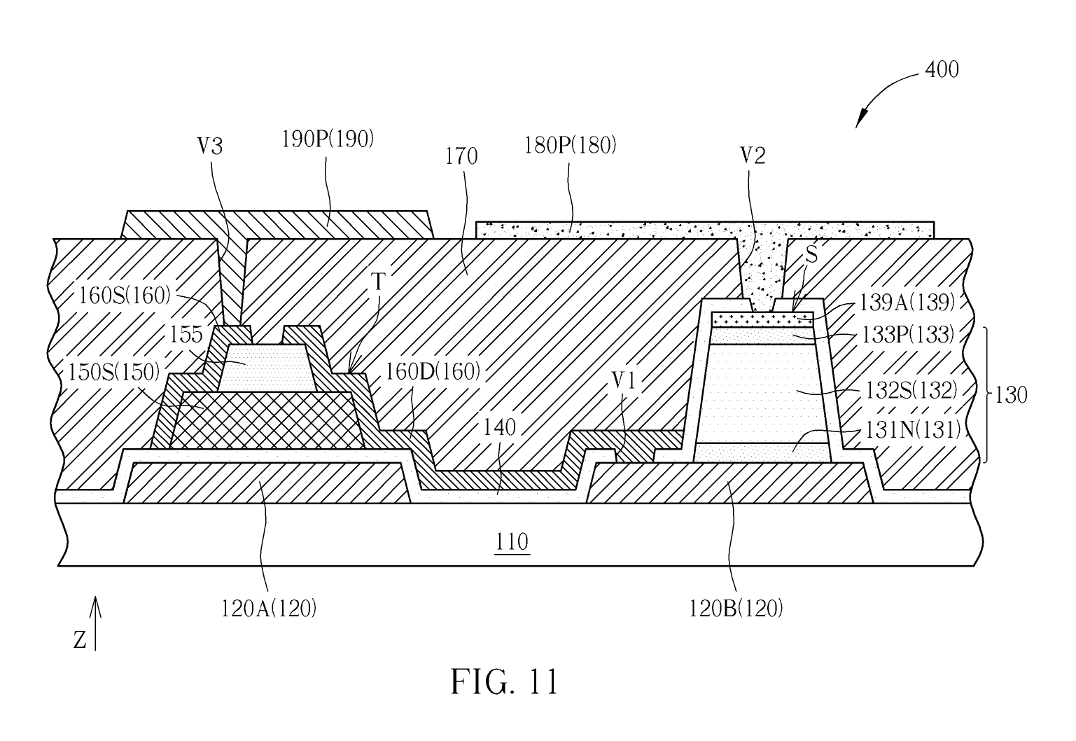

Referring to FIG. 11, FIG. 11 is a schematic diagram illustrating alight sensing device according to a fourth embodiment of the present invention. As shown in FIG. 11, the difference between the light sensing device 400 of the present embodiment and the aforementioned third embodiment is in that the protection layer 170 of the present embodiment includes a third opening V3, and at least a portion of the source electrode 160S is exposed from the third opening V3. Also, the light shielding pattern 190P is electrically connected to the source electrode 160S via the third opening V3, such that the light shielding pattern 190P will have a fixed potential, so as to keep the instability of the light shielding pattern 190P from affecting the operation of the light sensing device 400. In other words, the manufacturing method of the light sensing device 400 of the present embodiment further includes forming the third opening V3 in the protection layer 170, with the third opening V3 at least partially exposing the source electrode 160S, such that the light shielding pattern 190P formed hereafter can be electrically connected to the source electrode 160S via the third opening V3.

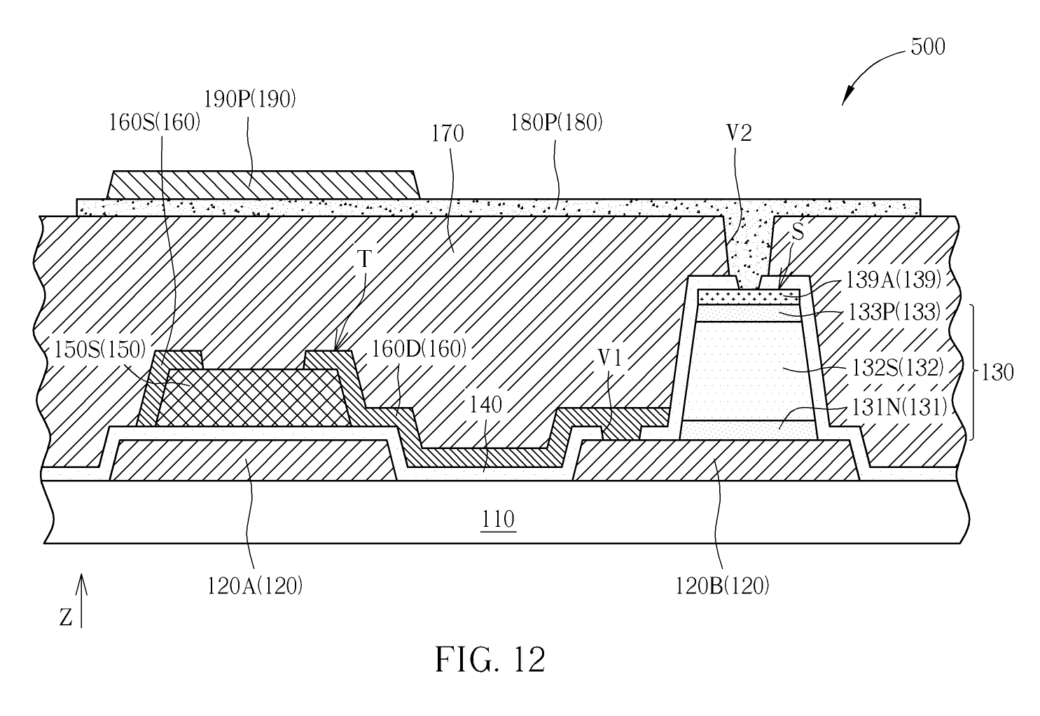

Referring to FIG. 12, FIG. 12 is a schematic diagram illustrating a light sensing device according to a fifth embodiment of the present invention. As shown in FIG. 12, the difference between the light sensing device 500 of the present embodiment and the aforementioned first embodiment is in that the control unit T of the present embodiment does not include the etching stop layer in the aforementioned first embodiment, and therefore a portion of the oxide semiconductor pattern 150S can directly contact the protection layer 170. The structure of the control unit T according to the present embodiment can also be applied to another embodiment of the present invention, in accordance with the practical requirements.

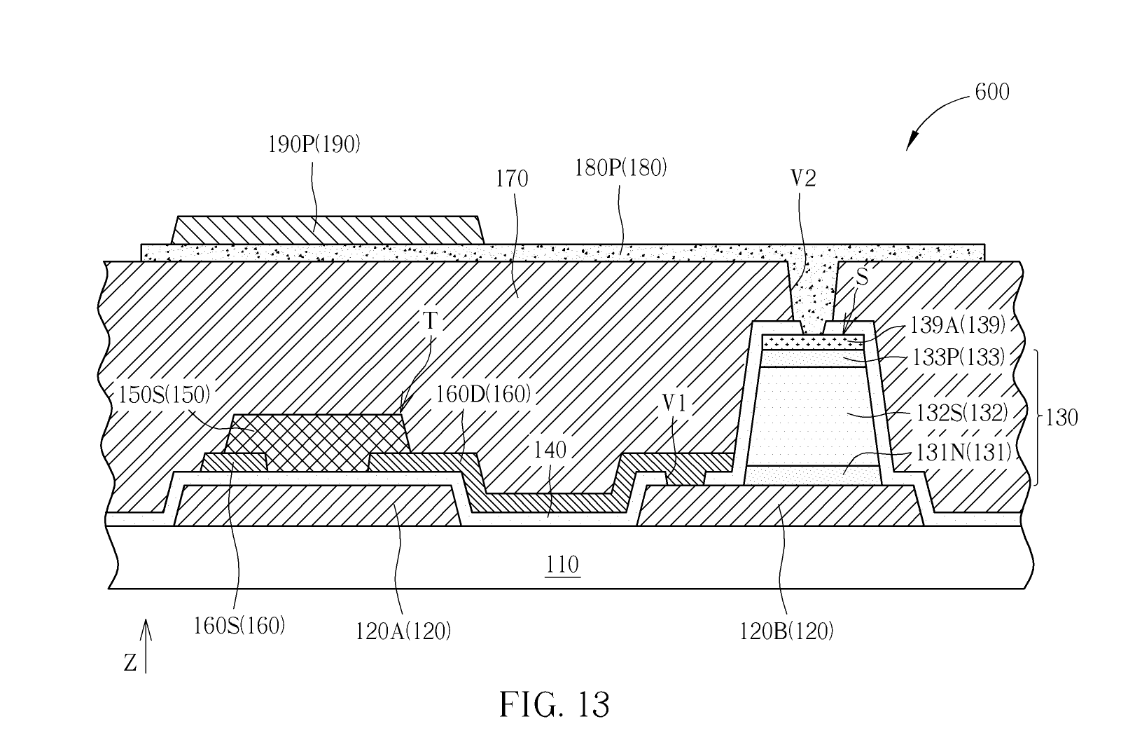

Referring to FIG. 13, FIG. 13 is a schematic diagram illustrating a light sensing device according to a sixth embodiment of the present invention. As shown in FIG. 13, the difference between the light sensing device 600 and the aforementioned first embodiment is in that the source electrode 160S of the present embodiment is partially disposed between the oxide semiconductor pattern 150S and the gate electrode 120A, and the drain electrode 160D is partially disposed between the oxide semiconductor pattern 150S and the gate electrode 120A. In other words, in the manufacturing method of the light sensing device 600 according to the present embodiment, the source electrode 160S and the drain electrode 160D are formed before the oxide semiconductor pattern 150S is formed, and the oxide semiconductor pattern 150S covers a portion of the source electrode 160S, a portion of the drain electrode 160D, and the gate insulation layer exposed between the source electrode 160S and the drain electrode 160D. The control unit T of the present embodiment is a coplanar thin film transistor, and the aforementioned structure can also be applied to another embodiment of the present invention, in accordance with the practical requirements.

In summary, through the light sensing device and the manufacturing method thereof, the sensing unit is formed firstly, and the oxide semiconductor pattern in the control unit is formed after the sensing unit is formed, such that it is sufficient to keep the manufacturing process of the sensing unit from affecting the electric property of the oxide semiconductor pattern, and to achieve the purpose of improving the component quality of the control unit and increasing the yield of the products. In addition, in the present invention, an insulation pattern is formed before the gate insulation layer is formed, to cover the light sensing unit, with such insulation pattern to make up for the inadequate protection to the light sensing diode due to limited material and thickness of the gate insulation layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light sensing device, comprising:
a substrate;
a control unit, disposed on the substrate, the control unit comprising:
a gate electrode;
a gate insulation layer, disposed on the gate electrode;
an oxide semiconductor pattern, disposed on the gate insulation layer; and
a source electrode and a drain electrode, wherein the source electrode and the drain electrode are disposed corresponding to the oxide semiconductor pattern; and
a sensing unit, disposed on the substrate, and the sensing unit comprising:
a bottom electrode;
a light sensing diode, disposed on the bottom electrode; and
a top electrode, disposed on the light sensing diode, wherein the gate insulation layer partially covers the top electrode, the gate insulation layer has a first opening partially exposing the bottom electrode, and the drain electrode is electrically connected to the bottom electrode via the first opening.

2. The light sensing device according to claim 1, further comprising:
a protection layer, covering the control unit and the light sensing unit;
a second opening, penetrating the protection layer and the gate insulation layer to at least partially expose the top electrode; and
a transparent conductive pattern, disposed on the protection layer, wherein the transparent conductive pattern is electrically connected to the top electrode via the second opening.

3. The light sensing device according to claim 2, further comprising: a light shielding pattern, disposed on the protection layer, wherein the light shielding pattern at least partially overlaps the control unit.

4. The light sensing device according to claim 3, wherein the light shielding pattern is disposed on the transparent conductive pattern and is electrically connected to the transparent conductive pattern.

5. The light sensing device according to claim 3, wherein the light shielding pattern does not overlap the transparent conductive pattern, and the light shielding pattern is electrically isolated from the transparent conductive pattern.

6. The light sensing device according to claim 3, wherein the protection layer has a third opening, the third opening at least partially exposes the source electrode, and the light shielding pattern is electrically connected to the source electrode via the third opening.

7. The light sensing device according to claim 1, further comprising an insulation pattern, partially overlapping the light sensing diode, and the insulation pattern being disposed between the light sensing diode and the gate insulation layer.

8. The light sensing device according to claim 1, wherein the light sensing diode comprises:
an N type semiconductor pattern;
an intrinsic semiconductor pattern, disposed on the N type semiconductor pattern; and
a P type semiconductor pattern, disposed on the intrinsic semiconductor pattern.

9. A manufacturing method of a light sensing device, comprising:
providing a substrate;
forming a gate electrode on the substrate;
forming a light sensing unit on the substrate, wherein the light sensing unit comprises:
a bottom electrode;
a light sensing diode, disposed on the bottom electrode; and
a top electrode, disposed on the light sensing diode;
forming a gate insulation layer, covering the substrate, the gate electrode and the light sensing unit;
forming an oxide semiconductor pattern on the gate insulation layer;
forming a first opening in the gate insulation layer, the first opening partially exposing the bottom electrode; and
forming a source electrode and a drain electrode on the gate insulation layer, wherein the gate electrode, the gate insulation layer, the oxide semiconductor pattern, the source electrode and the drain electrode are stacked to compose a control unit, and the drain electrode is electrically connected to the bottom electrode via the first opening.

10. The manufacturing method of the light sensing device according to claim 9, further comprising:
forming a protection layer, covering the control unit and the light sensing unit;
forming a second opening in the protection layer and the gate insulation layer, the second opening penetrating the protection layer and the gate insulation layer to at least partially expose the top electrode; and
forming a transparent conductive pattern on the protection layer, wherein the transparent conductive pattern is electrically connected to the top electrode via the second opening.

11. The manufacturing method of the light sensing device according to claim 10, further comprising forming alight shielding pattern on the protection layer, wherein the light shielding pattern at least partially overlaps the control unit.

12. The manufacturing method of the light sensing device according to claim 11, wherein the light shielding pattern does not overlap the transparent conductive pattern, and the light shielding pattern is electrically isolated from the transparent conductive pattern.

13. The manufacturing method of the light sensing device according to claim 12, further comprising forming a third opening in the protection layer, the third opening at least partially exposing the source electrode, and the light shielding pattern being electrically connected to the source electrode via the third opening.

14. The manufacturing method of the light sensing device according to claim 10, further comprising forming a light shielding pattern on the transparent conductive pattern, wherein the light shielding pattern at least partially overlaps the control unit, and the light shielding pattern is electrically connected to the transparent conductive pattern.

15. The manufacturing method of the light sensing device according to claim 9, further comprising forming an insulation pattern on the light sensing unit before forming the gate insulation layer.

16. The manufacturing method of the light sensing device according to claim 9, wherein the gate electrode and the bottom electrode are formed through patterning a same conductive layer.

17. The manufacturing method of the light sensing device according to claim 9, wherein a forming method of the light sensing diode comprising:
forming an N type semiconductor layer, an intrinsic semiconductor layer and a P type semiconductor layer on the bottom electrode sequentially; and
patterning the N type semiconductor layer, the intrinsic semiconductor layer and the P type semiconductor layer to form an N type semiconductor pattern, an intrinsic semiconductor pattern and a P type semiconductor pattern stacked with each other on the bottom electrode.

18. The manufacturing method of the light sensing device according to claim 9, wherein a forming method of the light sensing diode and the top electrode comprising:
forming an N type semiconductor layer, an intrinsic semiconductor layer and a P type semiconductor layer on the bottom electrode sequentially;
forming a transparent conductive layer on the P type semiconductor layer;
patterning the transparent conductive layer to form the top electrode; and
patterning the N type semiconductor layer, the intrinsic semiconductor layer and the P type semiconductor layer, to form an N type semiconductor pattern, an intrinsic semiconductor pattern and a P type semiconductor pattern stacked with each other on the bottom electrode.
